(19) United States
(12) Patent Application Publication
(10) Pub. No.: US 2015/0156860 A1
(43) Pub. Date: Jun. 4, 2015

(54) SOLDER RESIST OPENING STRUCTURE AND CIRCUIT BOARD

(71) Applicant: SAMSUNG ELECTRO-MECHANICS CO., LTD., Suwon (KR)

(72) Inventors: Chang Bo LEE, Suwon (KR); Dae Jo HONG, Hwasung (KR); Hyo Seung NAM, Hwasung (KR)

(73) Assignee: SAMSUNG ELECTRO-MECHANICS CO., LTD., Suwon (KR)

(21) Appl. No.: 14/278,522

(22) Filed: May 15, 2014

(30) Foreign Application Priority Data
Dec. 2, 2013 (KR) 10-2013-0148573

(51) Int. Cl. H05K 1/02

(52) U.S. Cl. CPC H05K 1/02; H05K 2201/2081

(57) ABSTRACT

A solder resist opening structure that exposes an electrode pad through a solder resist opening. The solder resist opening has a bottom diameter of about 80 μm or less with a first tolerance less than about 2.5 μm, the bottom diameter being smaller than a diameter of the electrode pad; an inverted trapezoidal cross section with a top diameter larger than the bottom diameter; and a diameter difference between the top diameter and the bottom diameter of about 10 μm or more with a second tolerance less than about 2.5 μm

### CROSS-REFERENCE TO RELATED APPLICATIONS

This application claims the foreign priority benefit under 35 U.S.C. Section 119 of Korean Patent Application Serial No. 10-2013-0148573, entitled “SOLDER RESIST OPENING STRUCTURE AND CIRCUIT BOARD” filed on Dec. 2, 2013, which is hereby incorporated by reference in its entirety into this application.

### BACKGROUND

1. Field

Embodiments of the present invention relate to a solder resist opening structure and a circuit board. More particularly, embodiments of the present invention relate to a solder resist opening structure and a circuit board which prevent bump cracking in minute solder resist openings.

2. Description of the Related Art

In manufacturing a printed circuit board (PCB), solder resist openings (SR openings) are formed during the solder resist (SR) process to provide paths for electric connection to chips. As chips are highly integrated, so are circuit boards; accordingly, such circuit boards need to be compact. In terms of solder resist (SR), a pitch between openings needs to be shorter, and the size of the solder resist opening (SRO) itself also needs to be smaller. Unfortunately, bump cracking arise with the shorter pitch and smaller solder resist opening (SRO). In addition, bump bridging, bump missing and solder resist lift (SR lift) may arise.

With the shorter pitch and smaller solder resist opening (SRO), bump cracking is likely to occur in the vertically formed SRO. Since thermal shock may apply during a reflow process, bump cracking is likely to occur when the pitch is shorter and the solder resist opening (SRO) is smaller. Bump cracking occurs when stress is overly applied to edges of an SRO due to coefficient of thermal expansion (CTE) mismatch.

### CITATIONS

Korean Patent Laid-Open Publication No. 2009-0099481 (published on Sep. 22, 2009)

### SUMMARY

An aspect of the present invention is to provide a solder resist opening structure and a circuit board which prevent bump cracking in minute solder resist openings.

According to an exemplary embodiment of the present invention, there is provided a solder resist opening structure that has a bottom diameter of 80 μm or less with a first tolerance and exposes an electrode pad through a solder resist opening, wherein: the bottom diameter is smaller than a diameter of the electrode pad; the structure has an inverted trapezoid shape with a top bottom diameter larger than the bottom diameter in a cross section; a diameter difference between the top diameter and the bottom diameter is 10 μm or more with the second tolerance and increases as the bottom diameter decreases; and the first tolerance and the second tolerance are less than 2.5 μm.

The bottom diameter may be 50 μm or more with the first tolerance.

The bottom diameter may be 70 μm or less with the first tolerance, and the diameter difference may be 15 μm or more with the second tolerance.

A pitch between solder resist openings may be 90 μm or more with the first tolerance, and a width of the upper surface of the solder resist between the solder resist openings may be 10 μm or more with the second tolerance.

A diameter of the electrode pad may be larger than that of the bottom diameter.

A gap between the electrode pads of adjacent solder resist openings may be 20 μm or more with the second tolerance.

A pitch between solder resist openings may be 90 μm or more with the first tolerance, and a gap between electrodes pads may be 20 μm or more with the second tolerance.

The top diameter may be larger than the diameter of the electrode pads, and a width of the upper surface of the solder resist between the solder resist openings may be 10 μm or more with the second tolerance.

According to another exemplary embodiment of the present invention, there is provided a circuit board, including: an insulation layer; a plurality of electrode pads formed on the insulation layer; and a solder resist having a plurality of solder resist openings, each of which exposes the respective electrode pads, wherein the solder resist openings have the solder resist opening structure as described above.

The bottom diameter of the solder resist opening structure may be 50 μm or more with the first tolerance.

A pitch between solder resist openings may be 90 μm or more with the first tolerance, and a width of the upper surface of the solder resist between the solder resist openings may be 10 μm or more with the second tolerance.

A diameter of the electrode pad may be larger than that of the bottom diameter.

In another example, a gap between the electrode pads may be 20 μm or more with the second tolerance.

Further, in one example, a pitch between solder resist openings may be 90 μm or more with the first tolerance, and a gap between electrodes pads may be 20 μm or more with the second tolerance.

The top diameter may be larger than the diameter of the electrode pads, and a width of the upper surface of the solder resist between the solder resist openings may be 10 μm or more with the second tolerance.

In another example, a printed circuit board comprises: an electrode pad; and a solder resist formed on the electrode pad and having an opening that exposes the electrode pad, the opening having a bottom diameter of about 80 μm or less and smaller than a diameter of the electrode pad, and an inverted trapezoidal cross section with a top diameter larger than the bottom diameter by a diameter difference of about 10 μm or more.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a view schematically showing the structure of a solder resist opening according to an exemplary embodiment of the present invention; and

FIG. 2 is a diagram illustrating the occurrence rates of bump cracking after a thermal shock test according to diameter differences between upper and lower diameters when the bottom diameter of a solder resist opening is 50 μm with a first tolerance.

### DESCRIPTION OF EMBODIMENTS

Exemplary embodiments of the present invention for accomplishing the above-mentioned aspects will be described with reference to the accompanying drawings. In the following descriptions, the same reference numerals refers to the same elements, and features well known to those skilled in the art may be omitted so as not to obscure the present invention.

In the specification, it will be understood that unless a term such as “directly” is used in a connection, coupling, or disposition relationship between one component and another component, one component may not only be ‘directly connected to’, ‘directly coupled to’ or ‘directly disposed to’ another element, but may also be connected to, coupled to, or disposed to another element, having the other element intervening therebetween.

Although a singular form is used in the present description, it may include a plural form as long as it is not opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

The accompanying drawings referred to in the present description may be examples for describing exemplary embodiments of the present invention. In the accompanying drawings, a shape, a size, a thickness, and the like, may be exaggerated in order to effectively describe technical characteristics.

First, the structure of a solder resist opening according to an exemplary embodiment of the present invention will be described in detail with reference to the accompanying drawings. In the drawings, a reference numeral referring to an element in a drawing may be omitted in another drawing in which the same element is depicted.

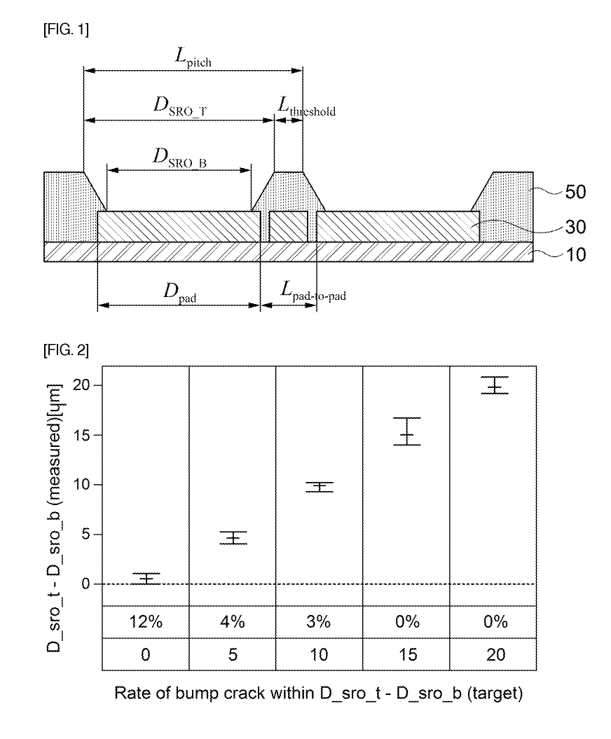

FIG. 1 is a view schematically showing the structure of a solder resist opening according to an exemplary embodiment of the present invention; and FIG. 2 is a diagram illustrating the occurrence rates of bump cracking after thermal shock test according to diameter differences between upper and lower diameters where the bottom diameter of a solder resist opening is 50 μm with the first tolerance.

Referring to FIG. 1 and Table 1 below, the structure of a solder resist opening according to an exemplary embodiment of the present invention has a bottom diameter of 80 μm or less. The tolerance of the bottom diameter is referred to here as the “first tolerance.” Referring to Table 1, no bump cracking is found with the bottom diameter of the solder resist opening above 85 μm, while bump cracking may or may not occur depending on the structure of the solder resist opening with the bottom diameter of the solder resist opening below 80 μm. Therefore, the inventors propose a structure that suppresses bump cracking in minute solder resist openings below 80 μm where bump cracking may or may not occur depending on the structure of the solder resist opening. An electrode pad 30 is exposed through the opening of the solder resist 50. The first tolerance of the bottom diameter may be 2.5 μm or less. In Table 1, target bottom diameter values (target D_{—sro—b}) have 5 μm gaps. Since all of the sums of average (Avg.) and deviation (Stdev.) have differences within 2.5 μm from the target bottom diameter value, the first tolerance may be less than 2.5 μm.

TABLE 1
(In μm)

| | | | | | | | | Fault |
|---|---|---|---|---|---|---|---|---|
| | Target | | | | | | | Rate of |
| Target | Diameter | D_{_{—}}ₛᵣₒ_{_{—}}_{b} | | D_{_{—}}ₛᵣₒ_{_{—}}ₜ | | D_{_{—}}ₛᵣₒ_{_{—}}ₜ − D_{_{—}}ₛᵣₒ_{_{—}}_{b} | | Bump |
| D_{_{—}}ₛᵣₒ_{_{—}}_{b} | Difference | Avg. | Stdev. | Avg. | Stdev. | Avg. | Stdev. | Cracking |
| 50 | 20 | 49.79 | 1.29 | 69.87 | 1.06 | 20.08 | 1.62 | 0% |
| | 15 | 50.74 | 1.35 | 65.92 | 0.83 | 15.18 | 1.52 | 0% |
| | 10 | 50.62 | 1.24 | 60.56 | 1.11 | 9.94 | 1.54 | 3.1% |
| | 5 | 50.83 | 1.15 | 55.82 | 1.3 | 4.99 | 1.74 | 4.2% |
| | 0 | 49.44 | 1.35 | 50.53 | 0.75 | 1.09 | 1.4 | 11.8% |
| 55 | 20 | 54.85 | 1.08 | 75.05 | 1.48 | 20.2 | 1.85 | 0% |
| | 15 | 54.82 | 1.42 | 69.54 | 1.35 | 14.72 | 1.94 | 0% |
| | 10 | 55.13 | 1.33 | 64.88 | 0.94 | 9.75 | 1.61 | 5.7% |
| | 5 | 54.76 | 0.49 | 60.32 | 0.86 | 5.56 | 1 | 10.1% |
| | 0 | 55.58 | 0.96 | 56.11 | 1.13 | 0.53 | 1.64 | 13.2% |
| 60 | 20 | 60.49 | 1.41 | 79.57 | 0.85 | 19.08 | 1.43 | 0% |
| | 15 | 59.37 | 1.06 | 74.13 | 1.14 | 14.76 | 1.59 | 0% |
| | 10 | 59.38 | 1.19 | 69.3 | 1.1 | 9.92 | 1.6 | 3.4% |
| | 5 | 60.62 | 1.3 | 66.33 | 1.12 | 5.71 | 1.66 | 8.9% |
| | 0 | 60.15 | 0.83 | 60.98 | 1.26 | 0.83 | 1.52 | 9.3% |
| 65 | 20 | 65.32 | 0.71 | 84.84 | 0.95 | 19.52 | 1.28 | 0% |
| | 15 | 65.72 | 1.26 | 80.01 | 1.47 | 14.29 | 1.86 | 0% |
| | 10 | 65.13 | 1.28 | 74.58 | 1.33 | 9.45 | 1.88 | 2.3% |
| | 5 | 66.08 | 1.13 | 70.33 | 1.09 | 4.25 | 1.56 | 8.0% |
| | 0 | 65.45 | 1.05 | 66.24 | 0.86 | 0.79 | 1.36 | 10.6% |
| 70 | 20 | 70.23 | 1.27 | 90.52 | 1.12 | 20.29 | 1.73 | 0% |
| | 15 | 69.96 | 1.4 | 85.53 | 1.03 | 15.57 | 1.75 | 0% |
| | 10 | 69.34 | 0.85 | 79.88 | 1.15 | 10.54 | 1.25 | 6.7% |
| | 5 | 69.68 | 1.33 | 74.46 | 0.86 | 4.78 | 1.62 | 7.7% |
| | 0 | 69.36 | 0.97 | 70.31 | 1.29 | 0.95 | 1.44 | 15.9% |
| 75 | 20 | 75.54 | 0.82 | 94.34 | 0.83 | 18.8 | 1.17 | 0% |
| | 15 | 75.61 | 1.21 | 90.77 | 1.13 | 15.16 | 1.58 | 0% |
| | 10 | 75.85 | 1.31 | 85.1 | 1.14 | 9.25 | 1.74 | 0% |
| | 5 | 76.06 | 0.95 | 80.99 | 1.46 | 4.93 | 1.74 | 8.3% |
| | 0 | 76.21 | 0.86 | 76.3 | 1.07 | 0.09 | 1.32 | 10.4% |
| 80 | 20 | 81.01 | 1.06 | 101.83 | 0.95 | 20.82 | 1.45 | 0% |
| | 15 | 80.85 | 1.05 | 96.95 | 1.36 | 16.1 | 1.63 | 0% |
| | 10 | 80.84 | 0.89 | 91.57 | 1.37 | 10.73 | 1.58 | 0% |
| | 5 | 80.01 | 0.98 | 85.52 | 1.6 | 5.51 | 1.84 | 7.1% |
| | 0 | 80.77 | 1.12 | 81.72 | 1.11 | 0.95 | 1.51 | 8.5% |
| 85 | 20 | 84.45 | 1.12 | 105.11 | 1.33 | 20.66 | 1.72 | 0% |
| | 15 | 84.76 | 1.01 | 99.48 | 0.86 | 14.72 | 1.43 | 0% |
| | 10 | 84.88 | 0.99 | 94.86 | 0.84 | 9.98 | 1.35 | 0% |
| | 5 | 84.31 | 0.99 | 89.95 | 1.13 | 5.64 | 1.36 | 0% |
| | 0 | 84.98 | 0.86 | 85.04 | 1.27 | 0.06 | 1.49 | 0% |
| 90 | 20 | 89.92 | 1.03 | 110.05 | 1.08 | 20.13 | 1.55 | 0% |
| | 15 | 89.41 | 0.85 | 105.35 | 1.06 | 15.94 | 1.28 | 0% |
| | 10 | 89.93 | 1.23 | 100.81 | 0.98 | 10.88 | 1.44 | 0% |
| | 5 | 90.57 | 1.29 | 95.88 | 1.45 | 5.31 | 1.99 | 0% |
| | 0 | 89.67 | 0.87 | 90.76 | 1.16 | 1.09 | 1.35 | 0% |

The expression “D_{—sro—b}” denotes the bottom diameter of a solder resist opening (SRO), the expression “D_{—sro—t}” denotes the top diameter of a solder resist opening, and the expression “D_{—sro—t}−D_{—sro—b}” denotes a diameter difference.

In Table 1, the thickness between the upper surface of an electrode pad and the surface of the solder resist SR was 15 μm. For example, the thickness of a solder resist may be 10 μm, 15 μm, 18 μm, and 21 μm as target values.

Referring to FIG. 1, the bottom diameter of the solder resist opening is less than a diameter of the electrode pad 30. Further, the solder resist opening has an inverted trapezoid shape in which the bottom diameter is greater than the top diameter. Referring to Table 1, the diameter difference between the top diameter and the bottom diameter is 10 μm or more and has a second tolerance. The second tolerance may be less than 2.5 μm. In Table 1, target bottom diameter values “Target D_{—sro—b}” vary in 5 μm increments. The sums of averages Avg. and deviations Stdev. of the diameter differences D_{—sro—t}−D_{—sro—b} between the top diameter and the bottom diameter have differences within approximately 2.5 μm from the target diameter difference values; thus, the second tolerance may be less than 2.5 μm.

In addition, the diameter difference between the top diameter and the bottom diameter increases as the bottom diameter decreases. In Table 1, no bump cracking occurred with the target diameter difference of 15 μm or more where the target bottom diameter of the solder resist opening is 70 μm or less, and no bump crack occurs with the target diameter difference of 10 μm or more where the target bottom diameter of the solder resist opening is 75 μm or more.

Referring to FIG. 1, if the bottom diameter D_{—sro—b} of the solder resist opening is 85 μm or more, no bump cracking occurs even if the diameter difference between the top diameter D_{—sro—t} and the bottom diameter D_{—sro—b} is 0 μm, i.e., even if the solder resist opening does not have an inverted trapezoid shape. Bump cracking may easily occur since a specific stress due to the choking effect on a bump in the top solder resist opening (SRO) becomes larger as the solder resist opening becomes smaller. To relieve this, a structure needs to be provided in which the choking effect may be reduced as much as possible.

According to embodiments of the present invention, there is provided a structure in which no bump cracking occurs in the solder resist opening having 80 μm or less with the first tolerance where bump crack occurs when the diameter difference between the top diameter D_{—sro—t} and the bottom diameter D_{—sro—b} is 0 μm. Therefore, a solder resist opening (SRO) having the bottom diameter D_{—sro—b} of 80 μm or less with the first tolerance was formed in an inverted trapezoid shape, in which the diameter difference D_{—sro—t}−D_{—sro—b} between the top diameter and the bottom diameter was 10 μm or more with the second tolerance. By adjusting the amount of exposure and the intensity of development, the solder resist opening SRO may be implemented as an inverted trapezoid shape to suppress bump cracking.

For example, the bottom diameter may be 50 μm or more with the first tolerance. If the bottom diameter D_{—sro—b} is too small, there may be a risk of bump missing, and thus the bottom diameter D_{—sro—b} may be 50 μm or more with the first tolerance. As can be seen from Table 2 below, if the bottom diameter D_{—sro—b} is 45 μm, bump missing occurs, and thus the bottom diameter D_{—sro—b} of the solder resist opening may be 50 μm or more.

For example, referring to FIG. 2 and Table 1, the bottom diameter D_{—sro—b} may be 70 μm or less with the first tolerance, and the diameter difference may be 15 μm or more with the second tolerance.

FIG. 2 shows results of reliability tests for thermal shock according to the diameter difference D_{—sro—t}−D_{—sro—b} between the top diameter and the bottom diameter when the bottom diameter D_{—sro—b} of the solder resist opening is 50 μm with the first tolerance. For the tests, in order to test bump cracking, 100 units of specimens having the bottom diameter D_{—sro—b} with the first tolerance were prepared per leg, and 20 units per leg were randomly chosen to be subjected to the tests for thermal shock. When the diameter differences D_{—sro—t}−D_{—sro—b} between the top diameter and bottom diameter with the second tolerance are 0 μm, 5 μm and 10 μm, the rates of bump cracking exhibit 11.8%, 4.2%, and 3.1%, respectively. No bump cracking is found if the diameter differences D_{—sro—t}−D_{—sro—b} between the top diameter and bottom diameter is 15 μm or more with the second tolerance.

In addition to the bottom diameter D_{—sro—b} of the solder resist opening being 50 μm with the first tolerance, test results for the bottom diameter D_{—sro—b} being up to 90 μm with 5 μm interval gaps are shown in Table 1. Referring to Table 1, when the bottom diameter D_{—sro—b} of the solder resist opening (SRO) are 50 μm, 55 μm, 60 μm, 65 μm, 70 μm, 75 μm, and 80 μm with the first tolerance, then the top diameter D_{—sro—t} of the solder resist opening (SRO) can be made to be more than 60 μm, 65 μm, 70 μm, 75 μm, 80 μm, 85 μm, and 90 μm with the first tolerance, respectively, in order to suppress bump cracking. For example, when the bottom diameters D_{—sro—b} are 50 μm, 55 μm, 60 μm, 65 μm, and 70 μm with the first tolerance, the top diameters D_{—sro—t} may be more than 65 μm, 70 μm, 75 μm, 80 μm, and 85 μm with the first tolerance, respectively. For example, when the bottom diameters D_{—sro—b} are 75 μm and 80 μm with the first tolerance, the top diameters D_{—sro—t} may be more than 80 μm and 90 μm with the first tolerance, respectively. These test results show that as the solder resist opening (SRO) becomes smaller, it should have an inverted trapezoid shape and the diameter difference between the top diameter and the bottom diameter also should be larger.

Now, a structure of solder resist opening according to an exemplary embodiment of the present invention will be described with reference to Table 2.

TABLE 2
(In μm)

| | | | | | | | Bump | Bump |
|---|---|---|---|---|---|---|---|---|
| | | | | | | SR lift | Missing | Bridging |
| L_{_{—}}_{pitch} | L_{_{—}}ₚ₋ₜₒ₋ₚ | D_{_{—}}ₛᵣₒ_{_{—}}ₜ | D_{_{—}}ₛᵣₒ_{_{—}}_{b} | D_{_{—}}_{pad} | L_{_{—}}ₜₕᵣₑₛ | Rate | Rate | Rate |
| 90 | 21 | 60 | 45 | 69 | 30 | 0% | 17% | 0% |
| 90 | 21 | 65 | 50 | 69 | 25 | 0% | 5% | 0% |
| 90 | 21 | 70 | 55 | 69 | 20 | 0% | 0% | 0% |
| 90 | 21 | 75 | 60 | 69 | 15 | 0% | 0% | 0% |
| 90 | 21 | 80 | 65 | 69 | 10 | 0% | 0% | 0% |
| 90 | 21 | 85 | 70 | 69 | 5 | 100% | N/A | N/A |
| 110 | 33 | 70 | 55 | 77 | 40 | 0% | 8% | 0% |
| 110 | 33 | 75 | 60 | 77 | 35 | 0% | 3% | 0% |
| 110 | 33 | 80 | 65 | 77 | 30 | 0% | 0% | 0% |
| 110 | 33 | 85 | 70 | 77 | 25 | 0% | 0% | 0% |
| 110 | 33 | 90 | 75 | 77 | 20 | 0% | 0% | 0% |
| 110 | 33 | 95 | 80 | 77 | 15 | 12% | 0% | 10% |
| 130 | 45 | 80 | 65 | 85 | 50 | 0% | 5% | 0% |
| 130 | 45 | 85 | 70 | 85 | 45 | 0% | 1% | 0% |
| 130 | 45 | 90 | 75 | 85 | 40 | 0% | 0% | 0% |
| 130 | 45 | 95 | 80 | 85 | 35 | 0% | 0% | 0% |
| 130 | 45 | 100 | 85 | 85 | 30 | 0% | 0% | 23% |
| 130 | 45 | 105 | 90 | 85 | 25 | 4% | 0% | 38% |

The expression “L_{—pitch}” denotes a pitch between solder resist openings, the expression “L_{—p-to-p}” denotes a gap between electrode pads 30, the expression “D_{—pad}” denotes a diameter of an electrode pad, the expression “L_{—thres”} denotes a width of the upper surface of a solder resist between solder resist opening, the expression “SR lift Rate” denotes a rate of solder resist lift, the expression “Bump Missing Rate” denotes a rate of bump missing, and the expression “Bump Bridging Rate” denotes a rate of bump bridging. In Table 2, the values of L_{—pitch}, D_{—sro—t}, D_{—sro—b}, D_{—pad}, and L_{—thres} are quantified including errors.

For example, referring to Table 2, a pitch between solder resist openings L_{—pitch} may be 90 μm or more with the first tolerance. In Table 2, when the bottom diameter D_{—sro—b} is 55 μm, the top diameter D_{—sro—t} is 70 μm, and the width of the upper surface of the solder resist L_{—thres} is 20 μm, when the bottom diameter D_{—sro—b} is 60 μm, the top diameter D_{—sro—t} is 75 μm, and the width of the upper surface of the solder resist L_{—thres l is} 15 μm, and when the bottom diameter D_{—sro—b} is 65 μm, the top diameter D_{—sro—t} is 80 μm, and the width of the upper surface of the solder resist L_thres is 10 μm, all of the rate of the solder resist lift, the rate of bump missing, and the rate of bump bridging are 0%, and thus the pitch between solder resist openings L_pitch may be 90 μm or more.

Further, the width of the upper surface of the solder resist L_{—thres} may be 10 μm or more with the second tolerance. If the width of the upper surface of the solder resist L_{—thres} is too small, bump bridging is likely to happen. Referring to Table 2, the width of the upper surface of the solder resist L_{—thres} becomes larger as the bottom diameter D_{—sro—b} becomes smaller. For example, referring to Table 2, except when the diameter of an electrode pad D_{—pad} is equal to or smaller than the bottom diameter D_{—sro—b}, no bump bridging occurs where the width of the upper surface of the solder resist L_{—thres} is 10 μm or more.

In addition, referring to Table 2, a diameter D_{—pad} of an electrode pad 30 may be larger than the bottom diameter D_{—sro—b}, for example. In Table 2, because solder resist lifting may occur if the diameter of an electrode pad 30 is smaller than the bottom diameter, the diameter D_{—pad} of the electrode pad may be larger than the bottom diameter D_{—sro—b}.

For another example, when solder resist openings are adjacent to each other, the gap between electrodes pads 30 L_{—p-to-p} may be 20 μm or more with the second tolerance.

Further, in one example, the pitch between solder resist openings L_{—pitch} may be 90 μm or more with the first tolerance, and the gap between electrodes pads L_{—p-to-p} may be 20 μm or more with the second tolerance.

For example, the top diameter D_{—sro—t} may be larger than the diameter D_{—pad} of the electrode pad 30. Further, the width of the upper surface of the solder resist L_{—thres} may be 10 μm or more with the second tolerance.

Referring to Table 2, when the bottom diameter D_{—sro—b} of the solder resist opening SRO is 80 μm or less with the first tolerance and the solder resist opening has an inverted trapezoid shape, by adjusting the diameter of the electrode pad 30 D_{—pad}, the width of the upper surface of the solder resist L_{—thres} between solder resist openings, the pitch between solder resist openings L_{—pitch} and the like, problems such as bump missing, bump bridging and solder resist lift may be prevented. The bump bridging happens as the pitch becomes smaller and thus the bump-to-bump distance becomes shorter. In order to prevent this, the gaps between the upper surfaces of adjacent solder resist openings (SRO) should be as long as possible. As for the bump missing, as a pitch becomes smaller so does a SRO, such that bump missing may occur during bump ball mounting or reflow if the SRO is too small. As for the solder resist lift (SR lift), the areas on which a SR is attached on an electrode pad or an insulation layer or a build-up layer (PPG or ABF, for example) becomes smaller as a pitch becomes smaller, such that the solder resist lift is likely to happen. Further, the solder resist lift (SR lift) may occur during a reliability test or a packaging process even if it did not occur during the production process.

With the diameter differences D_{—sro—t}—D_{—sro—b} between the top diameter and the bottom diameter that prevent bump cracking, by performing tests on the pitch between solder resist openings L_{—pitch} and on the gap between electrodes pads 30 L_{—p-to-p}, bump bridging characteristics, bump missing characteristics, and solder resist lift characteristics may be evaluated. Table 2 shows test results of the pitch between solder resist openings L_{—pitch} and the gap between electrodes pads 30 L_{—p-to-p}.

Referring to Table 2, a structure may be possible in which the top diameter D_{—sro—t}>the diameter of the electrode pad 30 D_{—pad}>the bottom diameter D_{—sro—b}. The structure may be adjusted so that the SR lift, bump missing and bump bridging may not occur. Even in the structure in which the top diameter D_{—sro—t}>the diameter of the electrode pad 30 D_{—pad} >the bottom diameter D_{—sro—b}, if the bottom diameter D_{—sro—b} is small and the diameter of the electrode pad 30 D_{—pad} approximates the bottom diameter D_{—sro—b}, the SR lift may occur due to the alignment issue. If alignment was properly made, no SR lift occurred.

Next, a circuit board according to a second exemplary embodiment of the present invention will be described in detail with reference to the accompanying drawings. In the following description, reference will be made to the structure of the solder resist opening according to the first exemplary embodiment of the present invention described above and FIGS. 1 and 2. Therefore, redundant descriptions will be omitted. FIG. 1 is a view schematically showing the structure of a solder resist opening according to an exemplary embodiment of the present invention.

Referring to FIG. 1, the circuit board according to the exemplary embodiment includes an insulation layer 10, a plurality of electrode pads 30, and a solder resist 50. The insulation layer 10 may be formed of any insulating material used for circuit boards which is known or to be developed in the future.

The plurality of electrode pads 30 may be formed on the insulation layer 10. The electrode pads 30 are connected to a circuit pattern (not shown) formed on the insulation layer 10. The electrode pads 30 may be connected to one another via the circuit pattern or may be connected to a via that penetrates through the insulation layer 10 or a bump to be formed on the solder resist opening.

The solder resist (50) may be formed on the electrode pads 30 and on the insulation layer 10. The solder resist 50 may have solder resist opening formed thereon through which the electrode pads 30 are exposed. Referring to FIG. 1, the solder resist openings have one of the solder resist openings according to the first exemplary embodiment of the present invention.

For example, the solder resist openings have the bottom diameter of 80 μm or less with the first tolerance and expose the electrode pads 30 therethrough. The first tolerance of the bottom diameter may be less than 2.5 μm. The bottom diameter is smaller than the diameter of the electrode pads 30 and the solder resist openings have a cross section of an inverted trapezoidal shape in which the bottom diameter is larger than the top diameter. Referring to Table 1, the diameter difference between the top diameter and the bottom diameter is 10 μm or more and has a second tolerance. The second tolerance may be less than 2.5 μm. In addition, the diameter difference between the top diameter and the bottom diameter increases as the bottom diameter decreases.

For example, referring to Table 2, in order to prevent bump missing, the bottom diameter may be 50 μm or more with the first tolerance.

For example, referring to FIG. 2 and Table 1, the bottom diameter D_{—sro—b} may be 70 μm or less with the first tolerance, and the diameter difference may be 15 μm or more with the second tolerance.

Then, referring to Table 2, in an example, the pitch between solder resist openings may be 90 μm or more with the first tolerance, and the width of the upper surface of the solder resist 50 between the solder resist openings may be 10 μm or more with the second tolerance.

In another example, the diameter of the electrode pads 30 may be larger than the bottom diameter.

In another example, the gap between the electrode pads may be 20 μm or more with the second tolerance.

Further, in one example, the pitch between solder resist openings may be 90 μm or more with the first tolerance, and the gap between electrodes pads may be 20 μm or more with the second tolerance.

In another example, the top diameter of the electrode pads 30 may be larger than the diameter of the electrode pads 30, and the width of the upper surface of the solder resist 50 between the solder resist openings may be 10 μm or more with the second tolerance.

As set forth above, according to exemplary embodiment of the present invention, bump cracking in minute solder resist openings may be prevented.

In addition, according to exemplary embodiments of the present invention, bump bridging, bump missing and/or solder resist lift may be overcome.

It is obvious that various effects directly stated according to various exemplary embodiments of the present invention may be derived by those skilled in the art from various configurations according to the exemplary embodiments of the present invention.

The above-mentioned exemplary embodiments and the accompanying drawings are merely illustrative for facilitating the understanding of the present invention by those skilled in the art and not limiting the scope of the present invention. In addition, those skilled in the art would easily implement the various exemplary embodiments by reading the detailed description. Therefore, various exemplary embodiments of the present invention may be implemented in modified forms without departing from features of the present invention. In addition, the scope of the present invention should be defined by the claims and encompasses various modifications, alterations, and equivalents made by those skilled in the art.

What is claimed is:

1. A solder resist opening structure that has a solder resist opening and is exposing an electrode pad through the solder resist opening, the solder resist opening having:
a bottom diameter of about 80 μm or less with a first tolerance less than about 2.5 μm, the bottom diameter being smaller than a diameter of the electrode pad;
an inverted trapezoidal cross section with a top diameter larger than the bottom diameter; and
a diameter difference between the top diameter and the bottom diameter of about 10 μm or more with a second tolerance less than about 2.5 μm

2. The solder resist opening structure according to claim 1, wherein the bottom diameter is about 50 μm or more with the first tolerance.

3. The solder resist opening structure according to claim 1, wherein the diameter difference is about 15 μm or more with the second tolerance.

4. The solder resist opening structure according to claim 2, wherein the bottom diameter is about 70 μm or less with the first tolerance, and the diameter difference is about 15 μm or more with the second tolerance.

5. The solder resist opening structure according to claim 1, wherein the top diameter of the solder resist opening is larger than a diameter of the electrode pad.

6. The solder resist opening structure according to claim 1, wherein
the solder resist opening is disposed in plural as plural solder resist openings,
a pitch between a pair of solder resist openings is about 90 μm or more with the first tolerance, and
a width of an upper surface of a solder resist between the pair of solder resist openings is about 10 μm or more with the second tolerance.

7. The solder resist opening structure according to claim 2, wherein
the solder resist opening is disposed in plural as plural solder resist openings,
a pitch between a pair of solder resist openings is about 90 μm or more with the first tolerance, and
a width of an upper surface of a solder resist between the pair of solder resist openings is about 10 μm or more with the second tolerance.

8. The solder resist opening structure according to claim 4, wherein
the solder resist opening is disposed in plural as plural solder resist openings,
a pitch between a pair of solder resist openings is about 90 μm or more with the first tolerance, and
a width of an upper surface of a solder resist between the pair of solder resist openings is about 10 μm or more with the second tolerance.

9. The solder resist opening structure according to claim 1, wherein
the solder resist opening and the electrode pad are disposed in plural as plural solder resist openings respectively exposing plural electrode pads, and
a gap between the electrode pads of adjacent solder resist openings is about 20 μm or more with the second tolerance.

10. The solder resist opening structure according to claim 1, wherein
the solder resist opening and the electrode pad are disposed in plural as plural solder resist openings respectively exposing plural electrode pads, and
a pitch between a pair of solder resist openings is about 90 μm or more with the first tolerance, and
a gap between the respective electrode pads is about 20 μm or more with the second tolerance.

11. The solder resist opening structure according to claim 2, wherein
the solder resist opening and the electrode pad are disposed in plural as plural solder resist openings respectively exposing plural electrode pads, and
a pitch between a pair of solder resist openings is about 90 μm or more with the first tolerance, and
a gap between the respective electrode pads is about 20 μm or more with the second tolerance.

12. The solder resist opening structure according to claim 10, wherein
the top diameter of the solder resist openings is larger than a diameter of the electrode pad, and
a width of an upper surface of a solder resist between the solder resist openings is about 10 μm or more with the second tolerance.

13. A circuit board, comprising:
an insulation layer;
a plurality of electrode pads formed on the insulation layer; and
a solder resist having a plurality of solder resist opening structures according to claim 1, the solder resist opening of each of which exposes a respective electrode pad of the plurality of electrode pads.

14. The circuit board according to claim 13, wherein the bottom diameter of at least one of the solder resist opening structures is about 50 μm or more with the first tolerance.

15. The circuit board according to claim 13, wherein
a pitch between a pair of solder resist openings is about 90 μm or more with the first tolerance, and
a width of an upper surface of the solder resist between the solder resist openings is about 10 μm or more with the second tolerance.

16. The circuit board according to claim 17, wherein a gap between electrode pads is about 20 μm or more with a tolerance less than 2.5 μm.

17. The circuit board according to claim 16, wherein
a pitch between solder resist openings is about 90 μm or more with the first tolerance, and
a gap between the electrode pads is about 20 μm or more with a tolerance less than 2.5 μm.

18. The circuit board according to claim 19, wherein
the top diameter of the solder resist openings is larger than a diameter of the electrode pad, and
a width of an upper surface of a solder resist between the solder resist openings is about 10 μm or more with the second tolerance.

19. A circuit board comprising:
an electrode pad; and
a solder resist formed on the electrode pad and having an opening exposing the electrode pad, the opening having
a bottom diameter of about 80 μm or less and smaller than a diameter of the electrode pad, and
an inverted trapezoidal cross section with a top diameter larger than the bottom diameter by a diameter difference of about 10 μm or more.

20. The circuit board according to claim 19, wherein the bottom diameter is about 70 μm or less and the diameter difference is about 15 μm or more.

21. The circuit board according to claim 19, wherein the bottom diameter and the diameter difference both have a tolerance less than about 2.5 μm.

22. The circuit board according to claim 19, wherein
the electrode pad is disposed in plural as a pair of electrode pads,
the opening is disposed in plural in the solder resist as a pair of openings each exposing a respective one the electrode pads,
a gap between the electrode pads is about 20 μm or more, and
a pitch between the openings is about 90 μm or more.
